(19) United States
(12) Patent Application Publication
(10) Pub. No.: US 2011/0235286 A1
(43) Pub. Date: Sep. 29, 2011

(54) DISPLAY PANEL MODULE AND DISPLAY APPARATUS

(75) Inventors: Hiromi KITAYAMA, Kyoto (JP); Munehiko OGAWA, Kyoto (JP); Tomoya ISHIKAWA, Osaka (JP); Hiroshi KOJIMA, Shiga (JP); Kazuyoshi NISHI, Kyoto (JP); Tooru SUYAMA, Kyoto (JP)

(73) Assignee: PANASONIC CORPORATION, Osaka (JP)

(21) Appl. No.: 13/155,815

(22) Filed: Jun. 8, 2011

Related U.S. Application Data
(63) Continuation of application No. PCT/JP2010/006389, filed on Oct. 29, 2010.

(30) Foreign Application Priority Data
Dec. 10, 2009 (JP) 2009-280275

(51) Int. Cl. H05K 1/18

(52) U.S. Cl. 361/749

(57) ABSTRACT

An object of the present invention is to provide a display panel module which enhances, in a display panel module, heat dissipation characteristics of a driving circuit element without reducing the number of display panels to be taken, and allows reduction in the number of display circuit elements. The display panel module according to the present invention includes: a film package; a display panel; a plurality of first electrodes connected to the film package; a plurality of second electrodes provided at a larger pitch than the first electrodes connected to the display panel; and a flexible printed circuit board 10 that relays pixel data between the film package 5 and the display panel.

### CROSS REFERENCE TO RELATED APPLICATION

This is a continuation application of PCT application No. PCT/JP2010/006389 filed on Oct. 29, 2010, designating the United States of America.

### BACKGROUND OF THE INVENTION

(1) Field of the Invention

The present invention relates to display panel modules, and relates particularly to a display panel module which is intended for reduction in the number of circuit elements each incorporating a driving circuit for a display panel such as a liquid crystal panel (hereinafter, a driving circuit element), and which reduces costs for the display panel module.

(2) Description of the Related Art

In recent years, as a display apparatus to be used for a television set, a monitor, or the like, the market for flat panel display apparatuses such as a liquid crystal panel, a plasma display panel, and an organic EL panel has been growing. In addition, along with the market growth, prices of flat panel display apparatuses are declining at an accelerating pace. This results in a further growth of the market for flat panel display apparatuses, and makes it essential to reduce costs for the display panel module and peripheral devices in manufacturing the flat panel display apparatuses.

Here, FIG. 17 shows a plan view showing a schematic configuration of a general display panel module used for a liquid crystal panel or the like. In this display panel module, a circuit element (hereinafter, a controller circuit element) 1, which incorporates a controller circuit for controlling a driving circuit element 6, is mounted on a wiring board (hereinafter, a controller board) 2. A signal output from the controller circuit element 1 is input into a film package 5 via a wiring board (hereinafter, a source board) 4 that is other than a cable 3 and the controller board 2. A plurality of film packages 5 are connected to the source board 4. Furthermore, via the wiring in the film package 5, the signal output from the controller circuit element 1 is input into the driving circuit element 6. Then, the driving signal output from the driving circuit element 6 is input into a display panel 9 via the wiring in the film package 5, and passes through a wiring region 7 in the display panel 9, to be input into a control line for driving pixels arranged in a matrix in a display region 8. By driving the pixels by the driving signal, an image is displayed on the display panel 9. Here described is an example of using two cables 3 and two source boards 4, but in some cases, the number of the cables 3 and the source boards 4 to be used is one or at least three for each.

As a measure for reducing costs for the display panel module as described earlier, a very useful method is a method of reducing the number of the driving circuit elements 6 or the film packages 5. Accordingly, as shown in FIG. 18, a technique of reducing the number of film packages 5 by incorporating a plurality of the driving circuit elements 6 in one film package 5 is disclosed (Patent Reference 1: Japanese Unexamined Patent Application Publication No. 2003-330041).

### SUMMARY OF THE INVENTION

However, according to a conventional configuration, along with decrease in the number of the film packages 5, it becomes more necessary to increase a vertical length Y of the wiring region 7 in order to secure the wiring region 7 in the display panel 9. This results in reduction in the number of panels to be taken from one glass substrate, and therefore does not reduce costs for a display panel module. In addition, when reducing, for the purpose of further reducing the costs, not only the number of the film packages 5 but also the number of the driving circuit elements 6, the vertical length Y of the wiring region 7 becomes longer. Here, the larger the display panel such as a television is, or the larger the number of pixels is, the more significant the problem becomes; thus, with the conventional configuration, it is difficult to reduce the number of driving circuit elements.

In addition, another problem in reducing the number of driving circuit elements 6 is that reduction in the number of driving circuit elements 6 results in increase in the number of outputs per one driving circuit element 6. In other words, this increases a circuit scale per one driving circuit element 6, thus increasing power consumption. As a result, the self-heating temperature of the driving circuit elements 6 increases to exceed a guarantee temperature of the driving circuit element 6 or causes deterioration in the characteristics of the driving circuit elements 6, thus deteriorating display quality.

An object of the present invention, conceived in view of the problems above, is to provide a display panel module or a display apparatus having a configuration which allows reduction in the number of driving circuit elements without decreasing the number of panels to be taken from a glass substrate, and allows enhancing heat dissipation characteristics of the driving circuit elements.

A display panel module according to an aspect of the present invention includes: a first flexible printed circuit board on which a circuit element for outputting pixel data is mounted; a display panel; and a second flexible printed circuit board having a plurality of first terminals connected to the first flexible printed circuit board and a plurality of second terminals each of which is provided for a corresponding one of the first terminals at a pitch larger than a pitch of the first terminals and is connected to the display panel and the corresponding one of the first terminals, the second flexible printed circuit board being for relaying the pixel data between the first flexible printed circuit board and the display panel.

In other words, a display panel module according to an aspect of the present invention connects an electrode of the film package on which the circuit element is mounted and an electrode of the display panel via at least one flexible printed circuit board, and secures, using the flexible printed circuit board, a wider connection region for connecting the flexible printed circuit board and the display panel than a connection region for connecting the film package and the flexible printed circuit board.

Here, in the display panel module according to an aspect of the present invention, it is preferable that the first flexible printed circuit board on which the circuit element is mounted be a film package. In addition, it is preferable that the second flexible printed circuit board be formed of the same material as the first flexible printed circuit board, specifically, the same film package as the film package used as the first flexible printed circuit board (however, a film package on which no chip is mounted).

The configuration as above produces an advantageous effect of reducing an area of the wiring region on the display panel, and increasing the number of display panels to be taken.

In the display panel module according to an aspect of the present invention, a plurality of circuit elements including the circuit element are mounted on the first flexible printed circuit board.

The configuration as above produces reducing package costs.

In the display panel module according to an aspect of the present invention, each of the plurality of circuit elements includes: a driving circuit element incorporating a driving circuit for the display panel; and one of a circuit element incorporating a controller circuit for controlling the driving circuit, and a circuit element incorporating a power circuit for generating a source voltage supplied to the driving circuit.

The configuration as above produces an advantageous effect of stabilizing operation characteristics of the driving circuit, and reducing members for configuring a display panel module, such as a wiring board.

In the display panel module according to an aspect of the present invention, the second terminals are arranged along a side of the second flexible printed circuit board, and a slit is provided on the side of the second flexible printed circuit board.

The configuration as above produces an advantageous effect of increasing reliability of connection between the second flexible printed circuit board and the display panel.

In the display panel module according to an aspect of the present invention, the slit is provided in a direction at 90 degrees with respect to the side of the second flexible printed circuit board.

The configuration as above produces an advantageous effect of improving efficiency in wiring between the second flexible printed circuit board and the display panel.

In the display panel module according to an aspect of the present invention, the side of the second flexible printed circuit board is separated into portions having an equal length by the slit.

The configuration as above facilitates a connection process for connecting the second flexible printed circuit board and the display panel, thus producing an advantageous effect of reducing man-hours.

In the display panel module according to an aspect of the present invention, the second flexible printed circuit board is formed into a trapezoidal shape having, as an upper base, a side along which the first terminals are arranged, and having, as a lower base, a side along which the second terminals are arranged.

The configuration as above suppresses size of the second flexible printed circuit board to a minimum, thus producing an advantageous effect of reducing costs for the second flexible printed circuit board.

The display panel module according to an aspect of the present invention further includes two second flexible printed circuit boards each being the second flexible printed circuit board, and the second terminals of the two second flexible printed circuit boards are connected to a same side of the display panel.

In the display panel module according to an aspect of the present invention, each of the two second flexible printed circuit boards is formed into a trapezoidal shape having, as an upper base, the side along which the first terminals are arranged, and having, as a lower base, the side along which the second terminals are arranged, and one of two sides connecting the upper and lower bases form an angle of 90 degrees with respect to each of the upper and lower bases.

The configuration as above increases the number of the second flexible printed circuit boards to be taken, thus producing an advantageous effect of cost reduction.

In the display panel module according to an aspect of the present invention, the first terminals are arranged in a staggered manner.

The configuration as above reduces the number of driving circuit elements, and thus suppresses, even when the number of outputs per driving circuit element is increased, increase in the area where the first terminals for connecting the film package and the second flexible printed circuit board are arranged, thus producing an advantageous effect of reducing package costs.

In the display panel module according to an aspect of the present invention, on the second flexible printed circuit board, a wire connected to a predetermined line of the first terminals arranged in the staggered manner and a wire connected to a line different from the predetermined line run in opposite directions.

The configuration as above allows reducing a wiring pitch of the film package to half a wiring pitch of the second flexible printed circuit board, thus producing an advantageous effect of reducing package costs by reducing the size of the film package.

In the display panel module according to an aspect of the present invention, the first terminals are connected to two different sides of the first flexible printed circuit board.

In the display panel module according to an aspect of the present invention, the first terminals are connected to three different sides of the first flexible printed circuit board.

The configuration as above allows increasing the number of the first terminals connecting the film package and the second flexible printed circuit board, without increasing a width of the film package, thus producing an advantageous effect of reducing package costs.

In the display panel module according to an aspect of the present invention, resistance values of a plurality of wires from the first terminals to the second terminals in the second flexible printed circuit board are uniform or approximately uniform.

The configuration as above suppresses variation such as a voltage drop caused by wiring resistance of an output signal from the driving circuit element, thus producing an advantageous effect of suppressing deterioration in display characteristics in the display panel module.

In the display panel module according to an aspect of the present invention, the wires on the second flexible printed circuit board have different lengths, and in the second flexible printed circuit board, a longer wire is wider than a shorter wire.

The configuration as above allows easily suppressing variation such as a voltage drop caused by wiring resistance of an output signal from the driving circuit element, thus producing an advantageous effect of suppressing a deterioration in display characteristics in the display panel module.

A display apparatus according to an aspect of the present invention includes: the display panel module as described above; and a material having high heat dissipation characteristics and provided in contact with the circuit element.

The configuration as above allows enhancing heat dissipation characteristics of the driving circuit element and increasing circuit size per driving circuit element, that is, increasing the number of outputs, thus producing an advantageous effect of reduction in the number of the driving circuit elements.

In the display apparatus according to an aspect of the present invention, the material having high heat dissipation characteristics is a chassis portion.

The configuration as above allows enhancing heat dissipation characteristics of the driving circuit element without adding another heat-dissipating member, and increasing circuit size per driving circuit element, that is, increasing the number of outputs, thus producing an advantageous effect of reducing the number of the driving circuit elements.

In the display apparatus according to an aspect of the present invention, the chassis portion includes a projection in a contact portion with the circuit element.

The configuration as above allows increasing contact between the chassis portion and the driving circuit element to enhance the heat dissipation characteristics of the driving circuit element, and increasing circuit size per driving circuit element, that is, increasing the number of outputs, thus producing an advantageous effect of reducing the number of the driving circuit elements.

As described above, a display panel module and a display apparatus according to an aspect of the present invention produces an advantageous effect of cost reduction in the display panel module by allowing reduction in the number of driving circuit elements in the display panel module without increasing the wiring region on the display panel, that is, without decreasing the number of panels to be taken from the same glass substrate.

In addition, the display panel module and the display apparatus allow the driving circuit element mounted on the film package in the display panel to be in contact with a material having high heat dissipation characteristics, which is, for example, the chassis portion in the display panel module. In other words, enhancement of the heat dissipation characteristics increases the number of outputs per driving circuit element, which allows reduction in the number of driving circuit elements in the display panel module, thus producing an advantageous effect of reducing costs for the display panel module.

### FURTHER INFORMATION ABOUT TECHNICAL BACKGROUND TO THIS APPLICATION

The disclosure of Japanese Patent Application No. 2009-280275 filed on Dec. 10, 2009 including specification, drawings and claims is incorporated herein by reference in its entirety.

The disclosure of PCT application No. PCT/JP2010/006389 filed on Oct. 29, 2010, including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a plan view showing a schematic configuration of a display panel module according to a first embodiment of the present invention;

FIG. 2A is a cross-sectional view showing a schematic configuration of a display apparatus according to the first embodiment of the present invention;

FIG. 2B is a cross-sectional view showing a schematic configuration of a conventional display apparatus having a general configuration;

FIG. 2C is a cross-sectional view showing a schematic configuration of a display panel module in which a projection is provided in the chassis portion, according to the first embodiment of the present invention;

FIG. 3 is a plan view showing a layout of terminals on a flexible printed circuit board according to the first embodiment of the present invention;

FIG. 4 is a plan view showing a schematic configuration of a display panel module including a trapezoidal flexible printed circuit board according to a variation of the first embodiment of the present invention;

FIG. 5 is a plan view showing a schematic configuration of a display panel module in which a plurality of circuit elements are mounted on a film package, according to a variation of the first embodiment of the present invention;

FIG. 6 is a plan view showing a schematic configuration of a display panel module using a flexible printed circuit board having, along three sides, a connection region to be connected to the film package, according to a variation of the first embodiment of the present invention;

FIG. 7 is a plan view showing wiring within a flexible printed circuit board, according to a variation of the first embodiment of the present invention;

FIG. 8 is a plan view showing a schematic configuration of a display panel module using two separate flexible printed circuit boards, according to a second embodiment of the present invention;

FIG. 9A is a plan view showing a schematic configuration of a display panel module having two separate flexible printed circuit boards having a trapezoidal shape, according to a variation of the second embodiment of the present invention;

FIG. 9B is a diagram for describing a layout of the separate flexible printed circuit boards on a base board, according to a variation of the second embodiment of the present invention;

FIG. 10 is a plan view showing a schematic configuration of a display panel module using two separate flexible printed circuit boards having, along two sides, a connection region to be connected to the film package, according to a variation of the second embodiment of the present invention;

FIG. 11 is a plan view showing a schematic configuration of a display panel module in which a slit is provided in the flexible printed circuit board, according to a third embodiment of the present invention;

FIG. 12 is a plan view showing a schematic configuration of a display panel module in which a slit is provided in the flexible printed circuit board, according to a variation of the third embodiment of the present invention;

FIG. 13 is a plan view showing a schematic configuration of a display panel module in which a slit is provided in each of the separate flexible printed circuit boards, according to a variation of the third embodiment of the present invention;

FIG. 14A is a plan view showing a schematic configuration of a display panel module according to a fourth embodiment of the present invention (enlarged view extracting only a film package and a flexible printed circuit board);

FIG. 14B is a plan view (enlarged view of the connecting portion) showing a schematic configuration of a display panel module in which electrodes to be connected to the film package are arranged in a staggered manner in the flexible printed circuit board, according to the fourth embodiment of the present invention;

FIG. 14C is a plan view (enlarged view of the connecting portion) showing a schematic configuration of a display panel module in which electrodes to be connected to the film package are arranged in a single line in the flexible printed circuit board, according to the fourth embodiment of the present invention;

FIG. 15A is a plan view (a diagram showing an example of a wiring pattern in the flexible printed circuit board) showing a schematic configuration of a display panel module in which electrodes are arranged in a staggered manner in the connecting portion between the film package and the flexible printed circuit board, according to the fourth embodiment of the present invention;

FIG. 15B is a plan view (enlarged view of the connecting portion to the film package, which is provided in the flexible printed circuit board) showing a schematic configuration of a display panel module in which electrodes are arranged in a staggered manner in the connecting portion between the film package and the flexible printed circuit board, according to the fourth embodiment of the present invention;

FIG. 16 is a plan view showing a schematic configuration of a display panel module according to a variation of the fourth embodiment of the present invention;

FIG. 17 is a plan view showing a schematic configuration of a display panel module in an example of a conventional general configuration; and

FIG. 18 is a plan view showing a schematic configuration of a display panel module in an example of a conventional general configuration other than the configuration shown in FIG. 17.

### DESCRIPTION OF THE PREFERRED EMBODIMENTS

Hereinafter, embodiments of the present invention will be described with reference to the drawings. Note that the embodiments below illustrate essentially preferable examples, and are not intended to limit the scopes of the present invention, the applications, or usages thereof.

### First Embodiment

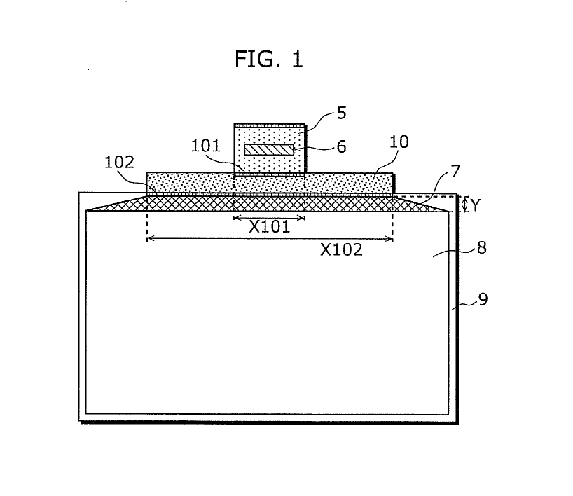

FIG. 1 is a plan view showing a schematic configuration of a display panel module according to a first embodiment of the present invention.

The display panel module includes: a film package 5, a display panel 9, and a flexible printed circuit board 10. The display panel module has a configuration such that, when the number of driving circuit elements 6 mounted on the film package 5 is reduced to one, electrodes (terminals) of the film package 5 and electrodes (terminals) of the display panel 9 are connected via the flexible printed circuit board 10. Here, by increasing a width X102 of a connecting portion 102 between the flexible printed circuit board 10 and the display panel 9 to be longer than a width X101 of the connecting portion 101 between the film package 5 and the flexible printed circuit board 10, it is possible to further decrease a vertical length Y of the wiring region 7 on the display panel 9 as compared to the case of directly connecting the film package 5 to the display panel 9, thus realizing reduction in costs for the display panel module. The driving circuit element 6 is a semiconductor integrated circuit element for a display circuit, which includes a driving circuit for the display panel 9. The film package 5 includes: the driving circuit element 6, electrodes, and wires connecting the electrode and the driving circuit element 6, and a flexible wiring board on which the driving circuit element 6 is mounted. Note that the driving circuit element 6 has been described as an example of the circuit element for output of pixel data such as a scan signal or a pixel signal, but is not limited to this.

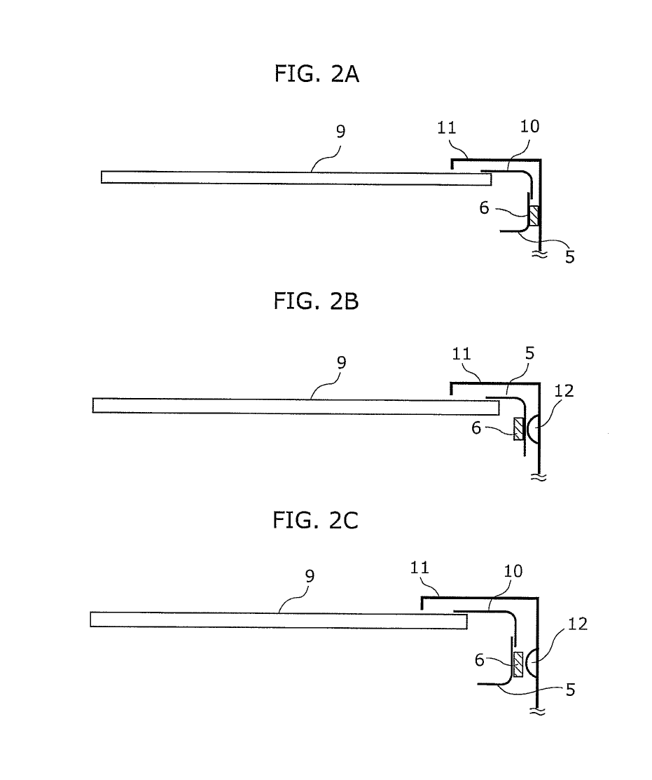

FIG. 2A is a cross-sectional view of a display apparatus according to the present embodiment.

The display apparatus includes: a display panel module shown in FIG. 1, and a chassis portion 11 which is a material having high heat dissipation characteristics and provided in contact with the driving circuit element 6 in the film package 5. According to the present embodiment, the driving circuit element 6 is exposed, in the display panel module, on a surface facing the chassis portion 11, with respect to the film package 5. Here, the chassis portion 11 is formed of a material having high conductivity such as metal. With this, compared to a conventional configuration in which the film package 5 is included between the driving circuit element 6 and the chassis portion 11 as shown in FIG. 2B, it is possible to release self-heating of the driving circuit element 6 into the chassis portion 11 more efficiently. This configuration is realized by interposing the flexible printed circuit board 10 between the film package 5 and the display panel 9. With this, it is possible to suppress temperature increase caused by self-heating of the driving circuit element 6, without adding another heat-dissipating material, even when the number of outputs per one driving circuit element 6 is increased, that is, when electric consumption per one driving circuit element 6 is increased due to increase in circuit size, thus realizing reduction in costs for the display panel module. In addition, as shown in FIG. 2C, it is possible to obtain a higher heat dissipation effect when the contact between the chassis portion 11 and the driving circuit element 6 is increased by providing a projection 12 in a point at which the chassis portion 11 contacts the driving circuit element 6 (a contact portion with the driving circuit element 6).

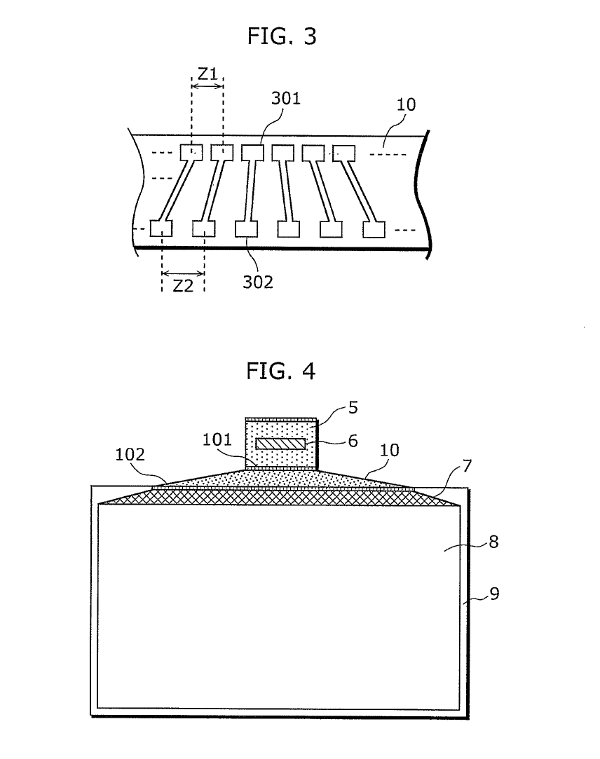

FIG. 3 is a plan view showing a layout of electrodes (terminals) of the flexible printed circuit board 10 according to the present embodiment.

The flexible printed circuit board 10 includes: a plurality of electrodes (first terminals) 301 connected to the film package 5; a plurality of electrodes (second terminals) 302 arranged at a pitch larger than a pitch of the electrodes 301 and connected to the display panel; wires connecting the electrodes 301 and the electrodes 302; and a flexible wiring board on which the wires are formed. Here, the pitch is a space between a center of a width in an arrangement direction of a predetermined electrode and a center of a width in an arrangement direction of an electrode located next to the predetermined electrode.

The flexible printed circuit board 10 has a rectangular shape, and pixel data from the film package 5 is transmitted from the film package 5 to the display panel 9 via the flexible printed circuit board 10.

The electrodes 301 are arranged along a predetermined side of the flexible printed circuit board 10, and this predetermined side is part of the connecting portion 101. On the other hand, the electrodes 302 are arranged on another side opposite to the predetermined side of the flexible printed circuit board 10, and this other side is part of the connecting portion 102.

(Variation 1)

Next, a variation of the display panel module according to the present embodiment is described with reference to FIG. 4.

As shown in FIG. 4, in the display panel module according to the present variation, it is possible to suppress an area of the flexible printed circuit board 10 to a minimum by forming a flexible printed circuit board into a trapezoidal shape, thus reducing costs for the display panel module.

The electrodes 301 to be connected to the film package 5 are arranged in line on an upper base of the flexible printed circuit board 10 having a trapezoidal shape, and the electrodes 302 to be connected to the display panel 9 are arranged in line on a lower base of the flexible printed circuit board. Note that the lower base of the trapezoidal shape has a longer side than the side of the upper base.

(Variation 2)

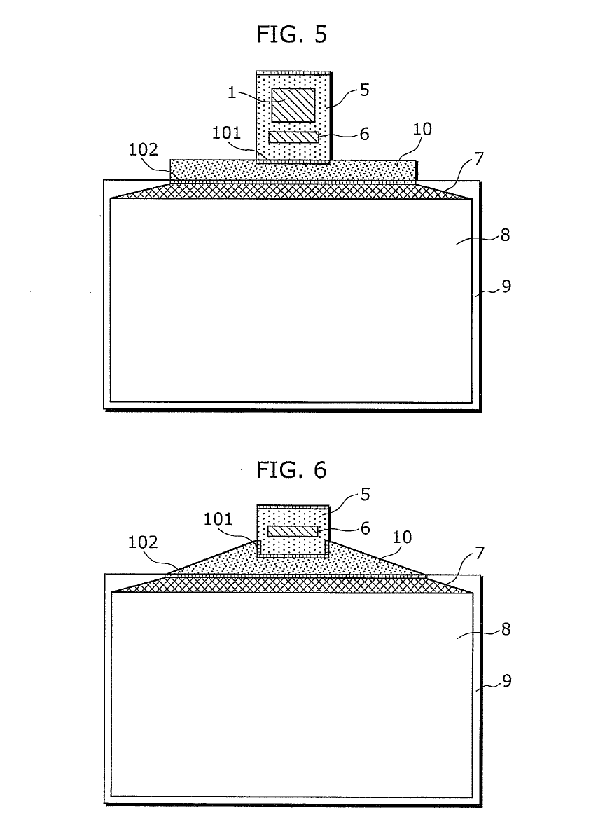

Next, another variation of the display panel module according to the present embodiment is described with reference to FIG. 5.

As shown in FIG. 5, the display panel module according to the present variation has a configuration such that a circuit element (controller circuit element) 1 on which a controller circuit for controlling a driving circuit of the display panel 9 and the driving circuit element 6 are mounted (incorporated) is mounted on one film package 5, that is, a configuration in which a plurality of circuit elements are mounted on one film package 5. The configuration of the present embodiment allows reducing, in the display panel module, the number of the driving circuit elements 6 to one. As a result, in the configuration of the conventional display panel module as shown in FIG. 17, it is possible to reduce the costs for the display panel module by reducing the numbers of cables 3, the source substrates 4, and the controller substrates 2 used for connecting the controller circuit element 1 and the plurality of driving circuit elements 6. Here, it is possible to provide a configuration which includes the controller circuit element 1 in FIG. 5 as a power supply circuit element that incorporates a power supply circuit for generating power to be supplied to the driving circuit element 6, or as both the controller circuit element and the power supply circuit element.

Note that in the present variation, the controller circuit element 1 and the driving circuit element 6 are mounted on one film package 5. However, as long as the driving circuit element 6, and at least one of the controller circuit element 1 and the power supply circuit element are mounted, the circuit elements to be mounted on one film package 5 are not limited to these controller circuit element 1 and driving circuit element 6.

(Variation 3)

Next, another variation of the display panel module according to the present embodiment is described with reference to FIG. 6.

As shown in FIG. 6, in the display panel module according to the present variation, a region of the connecting portion 101 to the flexible printed circuit board 10 is provided along three sides in the film package 5. This allows increasing the number of the electrodes 301 for connecting the film package 5 and the flexible printed circuit board 10, without increasing a width of the film package 5 as a result of increase in the number of outputs of the driving circuit element 6, thus reducing package costs.

The electrodes 301 in the flexible printed circuit board 10 which are to be connected to the film package 5 are connected to two different sides of the film package 5, more specifically, to three different sides of the film package 5. These three sides include: a side of the film package 5, which is opposite to a predetermined side of the flexible printed circuit board 10; and other two sides of the film package 5 each of which is adjacent to the side opposite to the predetermined side.

(Variation 4)

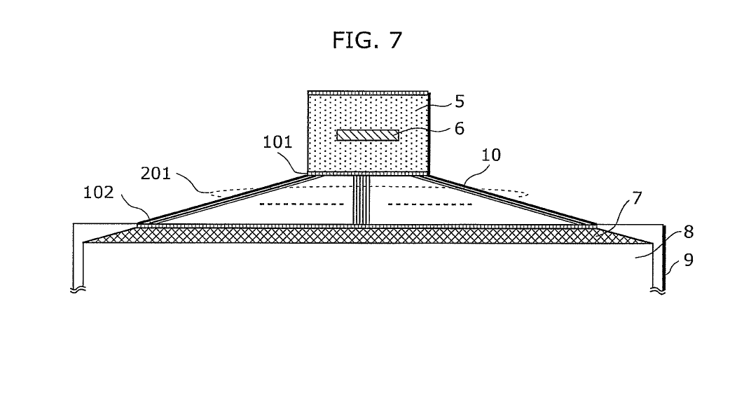

Next, another variation of the display panel module according to the present embodiment is described with reference to FIG. 7.

As shown in FIG. 7, in the display panel module according to the present variation, a wiring pattern in the flexible printed circuit board 10 is drawn in different wiring lengths. According to the configuration, in the flexible printed circuit board 10, a distance between the connecting portion 101 to the film package 5 and the connecting portion 102 to the display panel 9 is such that a wire 201 is shorter when closer to a center of the flexible printed circuit board 10 and longer when closer to an edge of the flexible printed circuit board 10. Here, a plurality of wires 201 in the flexible printed circuit board 10 are wires for transmitting, from the film package 5 to the display panel 9, a driving signal mainly for driving pixels of the display panel 9. Thus, when there is significant variation in resistance among the plurality of wires 201 in the flexible printed circuit board 10, such variation is likely to cause variation in influences on the driving signal such as a voltage drop, and accordingly cause deterioration in display characteristics of the display panel 9 such as occurrence of display unevenness; thus, for example, it is possible to suppress this problem by increasing the width of the wire 201 when it is longer, so as to decrease variation in resistance value in each wire. Note that it is preferable that the resistance value be uniform, but it goes without saying that it is possible to improve the display characteristics by approximating the resistance value to a uniform value if not completely equal.

The resistance value between the electrode 301 and the electrode 302 in each of the plurality of wires 201 in the flexible printed circuit board 10 is uniform or almost uniform. The plurality of wires 201 in the flexible printed circuit board 10 have different lengths, and in the flexible printed circuit board 10, a width of a longer wire 201 is greater than a width of a shorter wire 201.

### Second Embodiment

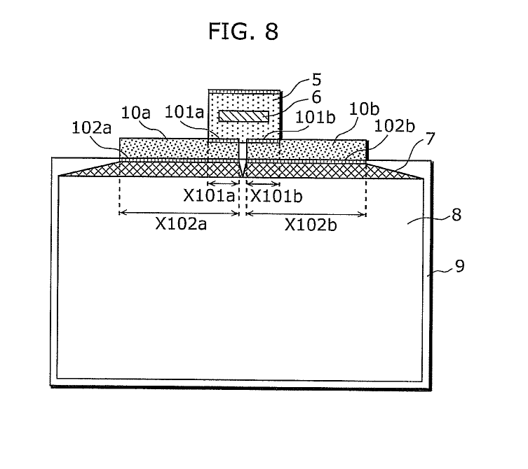

FIG. 8 is a plan view showing a configuration of a display panel module according to a second embodiment of the present invention.

The display panel module includes two separate flexible printed circuit boards 10a and 10b between the film package 5 and the display panel 9. In the display panel module according to the first embodiment as described earlier, when connecting the electrodes 302 of the flexible printed circuit board 10 and the electrodes of the display panel 9 by thermocompression bonding using anisotropically-conductive film (hereinafter, ACF) which is generally used as a method of bonding electronic components, it is necessary to design the pattern of each electrode such that the pattern includes a correction value, in consideration of distortion caused by difference in thermal expansion coefficient between the flexible printed circuit board 10 and the display panel 9. The longer the width X102 of the connecting portion 102 between the display panel 9 and the flexible printed circuit board 10 is, the more difficult it is to adjust this correction value. Thus, in the display panel module according to the present embodiment, the flexible printed circuit board 10 according to the first embodiment 1 is divided into two separate flexible printed circuit boards 10a and 10b as shown in FIG. 8. In other words, the two separate flexible printed circuit boards 10a and 10b are provided along a same side of the display panel 9, and the electrodes 302 in each of the two separate flexible printed circuit boards 10a and 10b are connected to the same side of the display panel. By dividing the connecting portion 102 between the flexible printed circuit board and the display panel 9 into two connecting portions 102a and 102b, it is possible to reduce difficulty in adjusting the correction value, thus increasing reliability of the connection between the display panel 9 and each of the separate flexible printed circuit boards 10a and 10b.

In addition, although not particularly shown, according to the second embodiment, as in the first embodiment described earlier, it is also possible to provide: a configuration which enhances heat dissipation characteristics by providing, in contact with the chassis portion 11 in the display panel module, the driving circuit element 6 mounted on the film package 5; a configuration in which a plurality of circuit elements are mounted on one film package 5; or a configuration which reduces variation in resistance value among the plurality of wires in the separate flexible printed circuit boards 10a and 10b.

(Variation 5)

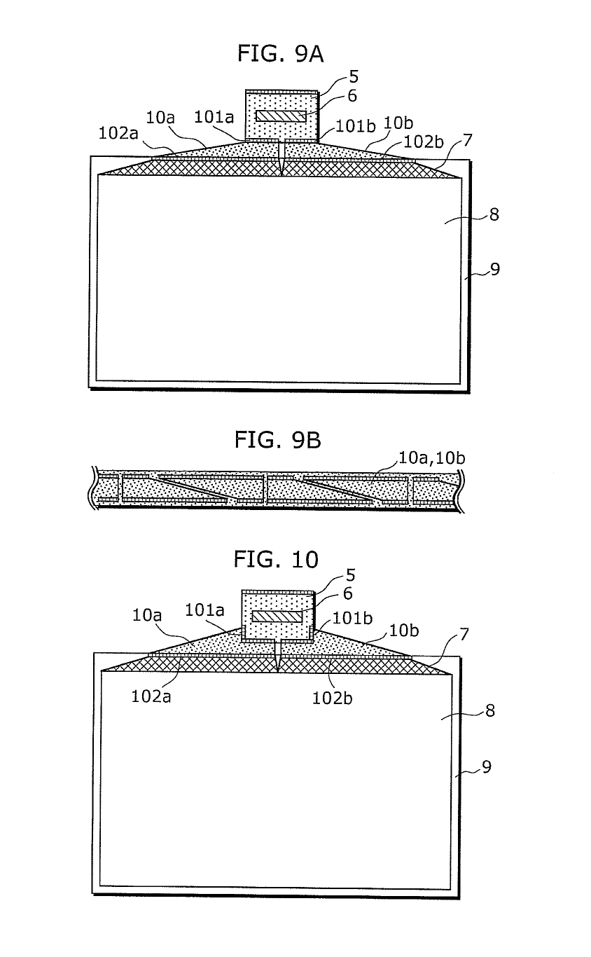

Next, a variation of the display panel module according to the present embodiment is described with reference to FIGS. 9A and 9B.

As shown in FIG. 9A, in the display panel module according to the present variation, each of the separate flexible printed circuit boards 10a and 10b has a trapezoidal shape. As with the first embodiment described earlier, by forming the separate flexible printed circuit boards 10a and 10b into a trapezoidal shape, it is possible to reduce costs for the flexible printed circuit boards 10a and 10b. Here, by forming, as shown in FIG. 9A, each of the separate flexible printed circuit boards 10a and 10b into a trapezoid in which a face bonded to the film package 5 is an upper base and a face bonded to the display panel 9 is a lower base, and in which an angle formed by one of nonparallel sides and each of the upper and lower bases is 90 degrees, it is possible to increase, as shown in FIG. 9B, the number of the separate flexible printed circuit boards 10a and 10b to be taken from the base board

The electrodes 301 to be connected to the film package 5 are arranged in line in the upper base of each of the separate flexible printed circuit boards 10a and 10b having a trapezoidal shape, and the electrodes 302 to be connected to the display panel 9 are arranged in line in the lower base of each of the separate flexible printed circuit boards 10a and 10b. One of the two sides connecting the upper and lower bases of the separate flexible printed circuit boards 10a and 10b forms an angle of 90 degrees with each of the upper and lower bases.

(Variation 6)

Next, another variation of the display panel module according to the present embodiment is described with reference to FIG. 10.

As shown in FIG. 10, the display panel module according to the present variation has a configuration in which areas of the connecting portions 101a and 101b for connecting to the separate flexible printed circuit boards 10a and 10b are provided along three sides of the film package 5. This, without increasing the width of the film package 5, allows increasing the number of electrodes 301 connecting the film package 5 and the separate flexible printed circuit boards 10a and 10b, that is, increasing the number of outputs from the driving circuit element 6.

### Third Embodiment

FIG. 11 is a plan view showing a configuration of a display panel module according to a third embodiment of the present invention.

The display panel module has a configuration in which: a slit 103 that is a cut in one of the sides of the flexible printed circuit board 10 which is the side along which electrodes 302 are arranged, and in the flexible printed circuit board 10, the connecting portion 102 to the display panel 9 is divided by the slit 103. By dividing the connecting portion 102 between the flexible printed circuit board 10 and the display panel 9 into four parts having widths X102a, X102b, X102c, and X102d, as in the second embodiment described above, it is possible to reduce difficulty in adjusting the correction value that is to be considered for performing thermocompression bonding using ACF on the flexible printed circuit board 10 and the display panel 9, thus increasing reliability of the connection between the flexible printed circuit board 10 and the display panel 9.

In addition, although not particularly shown, according to the present embodiment, as in the first or the second embodiment described earlier, it is also possible to provide: a configuration which includes the flexible printed circuit board 10 having a trapezoidal shape; a configuration which enhances heat dissipation characteristics by providing, in contact with the chassis portion 11 in the display panel module, the driving circuit element 6 mounted on the film package 5; a configuration in which a plurality of circuit elements are mounted on one film package 5; a configuration in which the connecting portion 101 for connecting to the flexible printed circuit board 10 is provided along three sides of the film package 5; or a configuration which reduces variation resistance value among the plurality of wires in the flexible printed circuit boards 10.

(Variation 7)

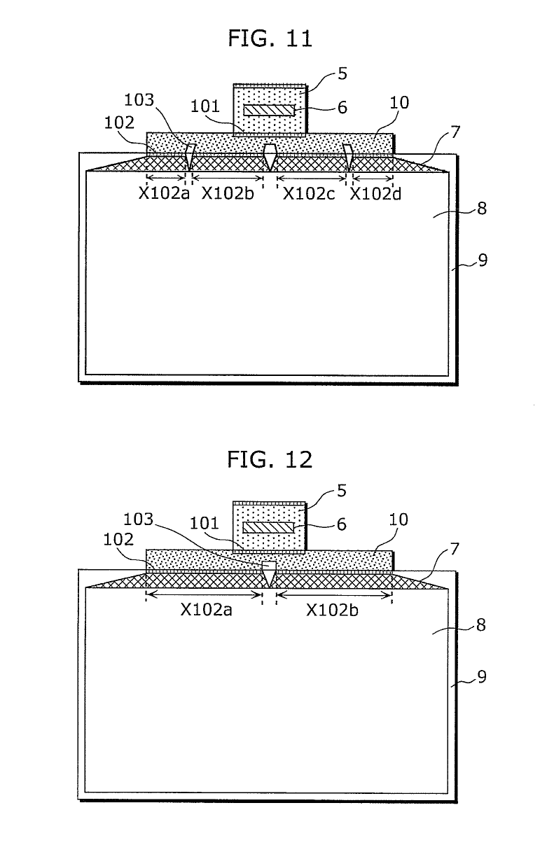

Next, a variation of the display panel module according to the present embodiment is described with reference to FIG. 12.

As shown in FIG. 12, in the display panel module according to the present variation, it is possible to improve wiring efficiency between the flexible printed circuit board 10 and the display panel 9 by providing the slit 103 in the flexible printed circuit board 10 in a direction at 90 degrees with respect to a side of the flexible printed circuit board 10, which is to be connected to the display panel 9 (a side along which each of the electrodes 302 are arranged). In addition, in the flexible printed circuit board 10, by dividing the side, of the flexible printed circuit board 10, which is to be connected to the display panel 9, into two equal sides by the slit 103, the connecting portion 102 is divided into two portions having equal widths X102a and X102b. As a result, by removing the necessity of separately considering the correction value for each point in the connecting portion 102 and removing the necessity of dividing equipment used for the connection according to each point, it is possible to facilitate processing in connecting the flexible printed circuit board 10 and the display panel 9.

(Variation 8)

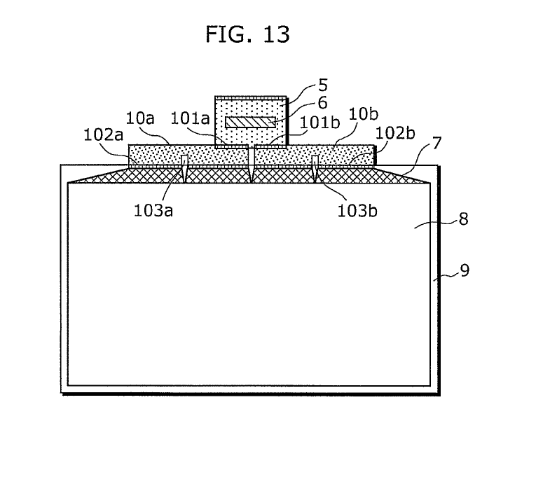

Next, another variation of the display panel module according to the present embodiment is described with reference to FIG. 13.

As shown in FIG. 13, the display panel module according to the present variation has a configuration in which slits 103a and 103b are provided, respectively, in the separate flexible printed circuit boards 10a and 10b described in the second embodiments above.

### Fourth Embodiment

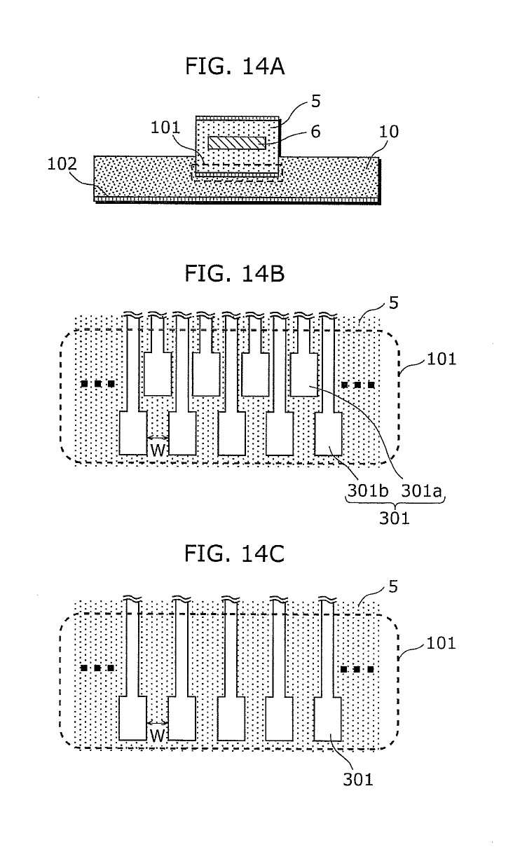

FIGS. 14A and 14B are plan views each showing a configuration of a display panel module according to a fourth embodiment of the present invention. Specifically, FIG. 14A is an enlarged view extracting the film package 5 on which the driving circuit element 6 is mounted and the flexible printed circuit board 10. FIG. 14B is an enlarged view of the connecting portion 101 in the configuration in which the electrodes 301 to be connected to the film package 5 are arranged in a staggered manner in the flexible printed circuit board 10.

FIG. 14C is a plan view showing a configuration of the display panel module according to the fourth embodiment of the present invention. Specifically, FIG. 14C is an enlarged view of the connecting portion 101 in the configuration in which the electrodes 301 to be connected to the film package 5 are arranged in a single line in the flexible printed circuit board 10.

As shown in FIG. 14B, in the configuration, the electrodes 301, in the flexible printed circuit board 10, for connecting the film package 5 and the flexible printed circuit board 10, are arranged in two different lines of electrodes 301a and 301b in a staggered manner, so that, as compared to electrodes arranged in the single line as shown in FIG. 14C, a larger number of electrodes can be provided without increasing the area of the connecting portion 101 and without changing space W between each electrode, that is, without increasing size of the film package 5, thus allowing reduction in package costs.

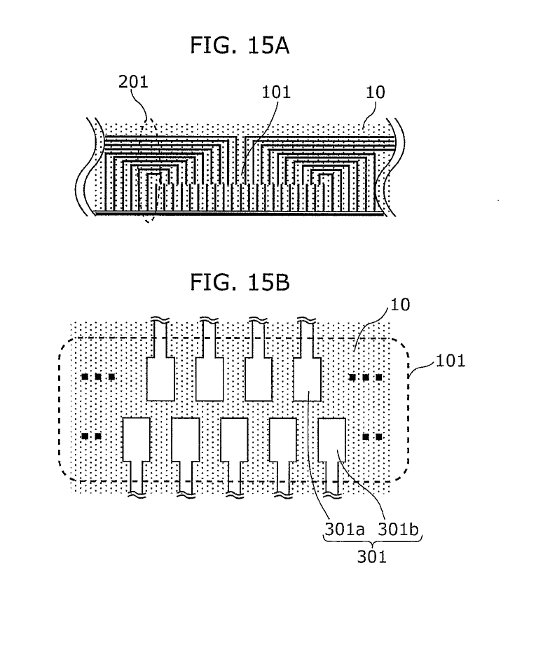

FIGS. 15A and 15B are plan views each showing a configuration of a display panel module according to the fourth embodiment of the present invention. Specifically, FIG. 15A, as with FIG. 14B, is an enlarged view showing the wires 201 laid out in the flexible printed circuit board 10, when the electrodes 301 in the connecting portion 101 between the film package 5 and the flexible printed circuit board 10 are arranged in a staggered manner. FIG. 15B is an enlarged view of the connecting portion 101 to the film package 5, in the flexible printed circuit board 10.

Generally, a minimum wiring pitch on Tape Career Package (TCP) or Chip On Film (COF), which is used as the film package 5, is currently approximately 25 μm to 30 μm at mass production level, whereas the minimum wiring pitch in the flexible printed circuit board 10 is approximately 50 μm to 60 μm. Here, as shown in FIG. 15B, by laying out the wires 201 in the flexible printed circuit board 10 such that wires from electrodes 301a in the upper line are guided into an upper side, and wires from electrodes 301b in the lower line are guided into a lower side, it is possible to provide the wires 201 in the flexible printed circuit board 10 at double the wiring pitch in the film package 5. In other words, it is possible to reduce package costs by removing the necessity of increasing the wiring pitch in the film package 5 according to the wiring pitch in the flexible printed circuit board 10 and removing the necessity of increasing the width of the film package 5 in order to secure the area of the connecting portion 101 to be connected to the flexible printed circuit board 10.

According to the configuration shown in FIG. 15B, in the flexible printed circuit board 10, wires to be connected to a predetermined line (the line of the electrodes 301a) among electrodes 301 arranged in a staggered manner, and wires to be connected to another line (the line of electrodes 301b) that is different from the predetermined line are guided to run in opposite directions.

In addition, although not shown, according to the present embodiment, as in the second embodiment described above, it is also possible to provide a configuration in which the film package 5 and the display panel 9 are connected to each other via the two separate flexible printed circuit boards 10a and 10b provided in between; or as in the third embodiment described above, it is also possible to provide a configuration in which, in the flexible printed circuit board 10, a side to be connected to the display panel 9 is divided by the slit. Furthermore, as in the first to the third embodiments described above, it is also possible to provide: a configuration which includes the flexible printed circuit board 10, or the separate flexible printed circuit boards 10a and 10b having a trapezoidal shape; a configuration which enhances heat dissipation characteristics by providing, in contact with the chassis portion 11 in the display panel module, the driving circuit element 6 mounted on the film package 5; a configuration which includes a plurality of circuit elements mounted on one film package 5; a configuration in which the connecting portion 101 for connecting to the flexible printed circuit board 10, or the connecting portions 101a and 101b for connecting to the separate flexible printed circuit boards 10a and 10b are provided along three sides of the film package 5; or a configuration which reduces variation in resistance value among the plurality of wires in the flexible printed circuit board 10, or the separate flexible printed circuit boards 10a and 10b.

Thus far, although a panel display module and a display apparatus according to the present invention have been described based on some embodiments, the present invention is not limited to these embodiments. Various variations and modifications by those skilled in the art would be possible within the scope of the present invention, without departing from the scope of the present invention. In addition, each constituent element in a plurality of embodiments may be arbitrarily combined within a scope not departing from the scope of the present invention.

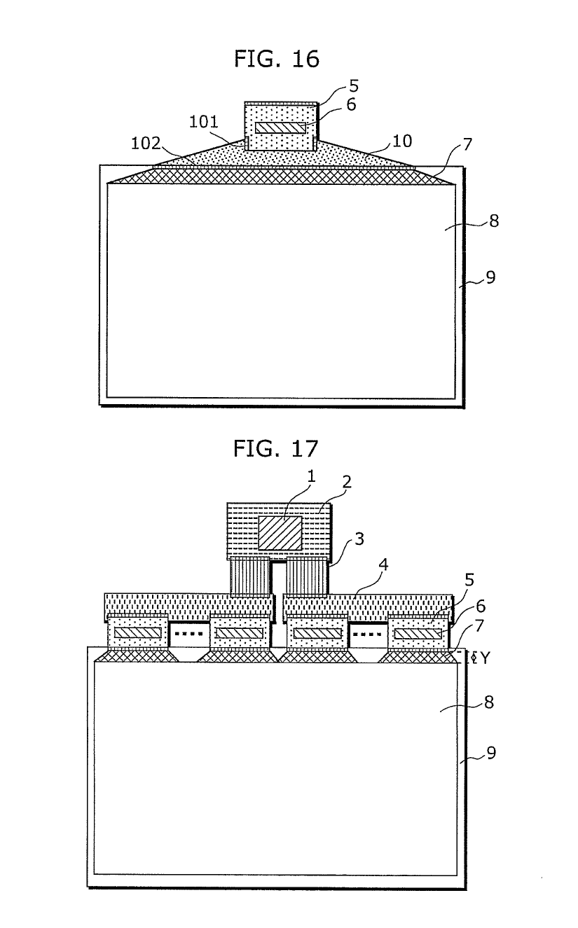

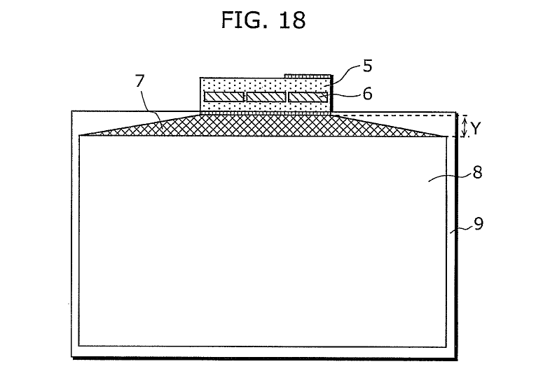

For example, in the above embodiments, the area of the connecting portion 101 in the film package 5, which is for connecting to the flexible printed circuit board 10, is provided along one or three sides. In other words, the electrodes 301 in the flexible printed circuit board 10 have been described as being connected to one or three different sides of the film package 5. However, as shown in the plan view of the display panel module in FIG. 16, the area of the connecting portion 101, in the film package 5, for connecting to the flexible printed circuit board 10 may be provided along two sides. In other words, the electrodes 301 in the flexible printed circuit board 10 which are to be connected to the film package 5 are connected to two different sides of the film package 5. These two sides include two sides of the film package 5 each of which is adjacent to a side opposite to the predetermined side of the flexible printed circuit board 10.

In addition, in the above embodiments, the film package 5 has been described as an example of the flexible printed circuit board on which circuit elements for output of pixel data are mounted, but the film package is not limited to this.

In addition, in the above embodiments, the chassis portion 11 has been described as a material having high heat dissipation characteristics which is provided in contact with the driving circuit element 6 in the film package 5, but the material may also be a heat-dissipating sheet provided in the display apparatus.

### INDUSTRIAL APPLICABILITY

The present invention, in order to achieve reduction in costs for a display panel module, can solve the conventional problems of increase in area of a wiring region in the display panel and heat generation in the driving circuit element in the display panel module, and is useful for a flat panel display apparatus such as a liquid crystal panel.

What is claimed is:

1. A display panel module comprising:
a first flexible printed circuit board on which a circuit element for outputting pixel data is mounted;
a display panel; and
a second flexible printed circuit board having a plurality of first terminals connected to said first flexible printed circuit board and a plurality of second terminals each of which is provided for a corresponding one of said first terminals at a pitch larger than a pitch of said first terminals and is connected to said display panel and the corresponding one of said first terminals, said second flexible printed circuit board being for relaying the pixel data between said first flexible printed circuit board and said display panel.

2. The display panel module according to claim 1,
wherein a plurality of circuit elements including the circuit element are mounted on said first flexible printed circuit board.

3. The display panel module according to claim 2,
wherein each of said plurality of circuit elements includes:
a driving circuit element incorporating a driving circuit for said display panel; and
one of a circuit element incorporating a controller circuit for controlling said driving circuit, and a circuit element incorporating a power circuit for generating a source voltage supplied to said driving circuit.

4. The display panel module according to claim 1,
wherein said second terminals are arranged along a side of said second flexible printed circuit board, and
a slit is provided on the side of said second flexible printed circuit board.

5. The display panel module according to claim 4,
wherein the slit is provided in a direction at 90 degrees with respect to the side of said second flexible printed circuit board.

6. The display panel module according to claim 4,
wherein the side of said second flexible printed circuit board is separated into portions having an equal length by the slit.

7. The display panel module according to claim 1,
wherein said second flexible printed circuit board is formed into a trapezoidal shape having, as an upper base, a side along which said first terminals are arranged, and having, as a lower base, a side along which said second terminals are arranged.

8. The display panel module according to claim 1, further comprising
two second flexible printed circuit boards each being said second flexible printed circuit board,
wherein said second terminals of said two second flexible printed circuit boards are connected to a same side of said display panel.

9. The display panel module according to claim 8,
wherein each of said two second flexible printed circuit boards is formed into a trapezoidal shape having, as an upper base, the side along which said first terminals are arranged, and having, as a lower base, the side along which said second terminals are arranged, and
one of two sides connecting the upper and lower bases form an angle of 90 degrees with respect to each of the upper and lower bases.

10. The display panel module according to claim 1,
wherein said first terminals are arranged in a staggered manner.

11. The display panel module according to claim 10,
wherein on said second flexible printed circuit board, a wire connected to a predetermined line of said first terminals arranged in the staggered manner and a wire connected to a line different from the predetermined line run in opposite directions.

12. The display panel module according to claim 1,
wherein said first terminals are connected to two different sides of said first flexible printed circuit board.

13. The display panel module according to claim 12,
wherein said first terminals are connected to three different sides of said first flexible printed circuit board.

14. The display panel module according to claim 1,
wherein resistance values of a plurality of wires from said first terminals to said second terminals in said second flexible printed circuit board are uniform or approximately uniform.

15. The display panel module according to claim 14,
wherein the wires on said second flexible printed circuit board have different lengths, and
in said second flexible printed circuit board, a longer wire is wider than a shorter wire.

16. The display panel module according to claim 1,
wherein said first flexible printed circuit board on which said circuit element is mounted is a film package.

17. A display apparatus comprising:
the display panel module according to claim 1; and
a material having high heat dissipation characteristics and provided in contact with said circuit element.

18. The display apparatus according to claim 17,
wherein said material having high heat dissipation characteristics is a chassis portion.

19. The display apparatus according to claim 18,
wherein said chassis portion includes a projection in a contact portion with said circuit element.
